(19) United States
(12) Patent Application Publication
(10) Pub. No.: US 2023/0223294 A1
(43) Pub. Date: Jul. 13, 2023

(54) EJECTOR PIN STRUCTURE, SEMICONDUCTOR PROCESSING DEVICE, AND METHOD FOR USING SEMICONDUCTOR PROCESSING DEVICE

(71) Applicant: CHANGXIN MEMORY TECHNOLOGIES, INC., Hefei City (CN)

(72) Inventor: Qiang RU, Hefie City (CN)

(73) Assignee: CHANGXIN MEMORY TECHNOLOGIES, INC., Hefei City (CN)

(21) Appl. No.: 17/662,698

(22) Filed: May 10, 2022

Related U.S. Application Data
(63) Continuation of application No. PCT/CN2022/081756, filed on Mar. 18, 2022.

(30) Foreign Application Priority Data
Jan. 7, 2022 (CN) 202210016216.1

(51) Int. Cl. H01L 21/687; H01J 37/32

(52) U.S. Cl. CPC H01L 21/68742; H01J 37/32724; H01J 2237/3321

(57) ABSTRACT

An ejector pin structure at least includes an end part and an ejector rod. The end part includes a convex structure and an inverted trapezoid-like structure located below the convex structure. The convex structure is configured to support an object to be processed. A projection area of the convex structure in a horizontal plane is less than a projection area of the inverted trapezoid-like structure in the horizontal plane.

### CROSS-REFERENCE TO RELATED APPLICATIONS

This is a continuation of International Patent Application No. PCT/CN2022/081756 filed on Mar. 18, 2022, which claims priority to Chinese Patent Application No. 202210016216.1 field on Jan. 7, 2022. The disclosures of these applications are hereby incorporated by reference in their entirety.

### BACKGROUND

In a semiconductor manufacturing process, the manufacturing of a wafer has very high requirements for the process. The whole process can be divided into many manufacture procedures. Each manufacture procedure will involve lifting and transferring of the wafer, and the requirements are usually met by means of an ejector pin structure. When a semiconductor (or a wafer) is processed by a semiconductor device, the wafer is supported by the ejector pin structure. An end part of the ejector pin structure will be in contact with a back surface of the wafer, for example, when the ejector pin structure of the semiconductor device GT3/GT/SE produced by Applied Materials, Inc. (AMAT) supports a wafer, the end part of the ejector pin structure will be in contact with the back surface of the wafer. At present, a contact area between the ejector pin structure and the wafer is large, and the ejector pin structure will be corroded to produce many particles when a machine is subjected to a cleaning process for a long time, so as to affect subsequent manufacture procedures, thereby affecting the yield of wafers.

### SUMMARY

The disclosure relates, but is not limited, to the technical field of semiconductor processing, and in particular, to an ejector pin structure, a semiconductor processing device, and a method for using the semiconductor processing device.

The embodiments of the disclosure provide an ejector pin structure, a semiconductor processing device, and a method for using the semiconductor processing device.

In a first aspect, the embodiments of the disclosure provide an ejector pin structure. The ejector pin structure at least includes an end part and an ejector rod. The end part includes a convex structure and an inverted trapezoid-like structure located below the convex structure. The convex structure is configured to support an object to be processed. A projection area of the convex structure in a horizontal plane is less than a projection area of the inverted trapezoid-like structure in the horizontal plane.

In a second aspect, the embodiments of the disclosure provide a semiconductor processing device, including a cavity; ejector pin structures as described above, located in the cavity and configured to support a semiconductor; and a lifting assembly, configured to drive the ejector pin structure to move up and down.

In a third aspect, the embodiments of the disclosure provide a method for using a semiconductor processing device. The device includes: a cavity and a lifting assembly. The cavity includes injector pin structures and a heating assembly. The ejector pin structures are configured to support a semiconductor. The ejector pin structure includes an ejector rod and an end part that are connected detachably. The end part includes a convex structure and an inverted trapezoid-like structure located below the convex structure. A projection area of the convex structure in a horizontal plane is less than a projection area of the inverted trapezoid-like structure in the horizontal plane. The heating assembly is located in the cavity and is configured to perform at least one of heating the semiconductor or carrying the semiconductor. A plurality of channels through which all ejector pin structures penetrate are formed in the heating assembly. The lifting assembly is configured to drive the ejector pin structure to move up and down. The method includes: opening the cavity; replacing the end part; and closing the cavity.

### BRIEF DESCRIPTION OF THE DRAWINGS

In the drawings which are not necessarily drawn to scale, similar reference numerals may describe similar parts in different figures. Similar reference numerals with different letter suffixes may represent different examples of similar parts. The drawings generally illustrate the various embodiments discussed herein by way of examples rather than limitation.

FIG. 1A is a schematic diagram illustrating a composition structure of an ejector pin structure.

FIG. 1B is a schematic diagram illustrating a positional relationship between the ejector pin structure and a heating assembly.

FIG. 1C is a first schematic diagram illustrating production of particles when an ejector pin structure is in contact with a back surface of a wafer.

FIG. 1D is a second schematic diagram illustrating production of particles when an ejector pin structure is in contact with a back surface of a wafer.

FIG. 2A is a first schematic diagram illustrating composition structures of an ejector pin structure provided by the embodiments of the disclosure.

FIG. 2B is a second schematic diagram illustrating composition structures of an ejector pin structure provided by the embodiments of the disclosure.

FIG. 3A is a first schematic diagram illustrating composition structures of a semiconductor processing device provided by the embodiments of the disclosure.

FIG. 3B is a second schematic diagram illustrating composition structures of a semiconductor processing device provided by the embodiments of the disclosure.

FIG. 3C is a third schematic diagram illustrating composition structures of a semiconductor processing device provided by the embodiments of the disclosure.

FIG. 3D is a fourth schematic diagram illustrating composition structures of a semiconductor processing device provided by the embodiments of the disclosure.

FIG. 4 illustrates an implementation flowchart of a method for using the semiconductor processing device provided by the embodiments of the disclosure.

FIG. 5 illustrates another implementation flowchart of a method for using the semiconductor processing device provided by the embodiments of the disclosure.

### DETAILED DESCRIPTION

Exemplary implementation modes of the disclosure will be described below in more detail with reference to the drawings. Although the exemplary implementation modes of the disclosure are shown in the drawings, it should be understood that, the disclosure may be implemented in various forms and should not be limited by the specific implementation modes elaborated herein. On the contrary, these implementation modes are provided to enable a more thorough understanding of the disclosure and to fully convey the scope of the disclosure to those skilled in the art.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, not all features of the actual embodiments are described here, and the known functions and structures are not described in detail.

In the drawings, the dimensions of layers, areas and elements and their relative dimensions may be exaggerated for clarity. Throughout, the same reference numerals represent the same elements.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers, and/or parts may be described with terms “first”, “second”, “third”, etc., these elements, components, areas, layers, and/or parts should not be limited by these terms. These terms are used only to distinguish one element, component, area, layer or part from another element, component, area, layer or part. Therefore, a first element, component, area, layer, or part discussed below may be represented as a second element, component, area, layer, or part without departing from the teaching of the disclosure. However, when the second element, component, area, layer, or part is discussed, it does not mean that the first element, component, area, layer, or part is necessarily presented in the disclosure.

The terms used herein are intended only to describe specific embodiments and are not a limitation of the disclosure. As used herein, singular forms “a/an”, “one”, and “said/the” may also be intended to include the plural forms, unless otherwise specified types in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups is not excluded. As used herein, terms “and/or” includes any and all combinations of the related listed items.

In order to understand an ejector pin structure provided by the embodiments of the disclosure better, the problems in the ejector pin structure are described first.

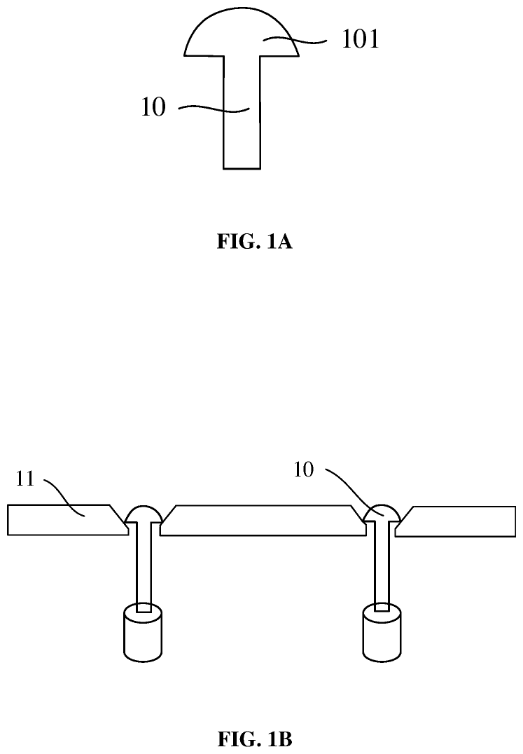

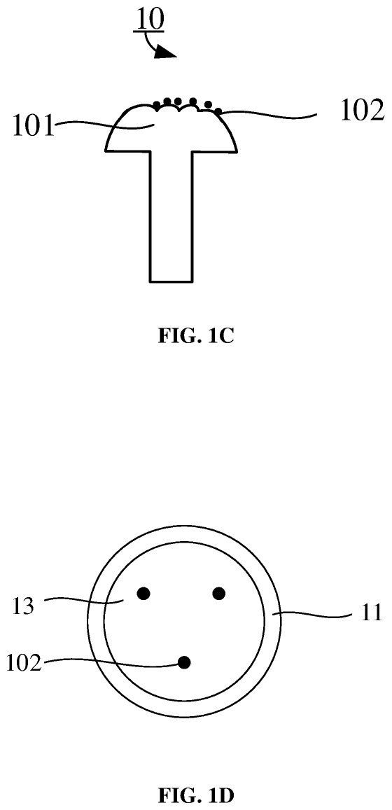

In the case that the semiconductor is processed by a machine, for example, a silicon nitride film is deposited on a wafer by a chemical vapor deposition method, an ejector pin structure will be in contact with a back surface of the wafer when the ejector pin structure supports the wafer. An ejector pin structure 10, which is shown in FIG. 1A, has a hemispherical end part 101 and an ejector rod, and the top 101 of the ejector pin structure is integrally connected to the ejector rod.

As shown in FIG. 1B, a heating assembly 11 has a channel through which the ejector pin structure 10 passes. A lifting assembly may drive the ejector pin structure 10 to move up and down. Since the end part of and the ejector rod of the ejector pin structure are integrated, and the heating assembly needs to be detached when the ejector pin structure is replaced, so that the replacement time is long.

During depositing the silicon nitride film, the machine needs to be subjected to a cleaning process, for example, a surface of the wafer, or the interior of a cavity is cleaned by using a clean gas or plasma, to remove impurities. Therefore, a problem that the ejector pin structure will be corroded when the machine is subjected to the cleaning process for a long time will be caused, so that particles exist at a contact position between a back surface of a wafer and an end part of the ejector pin structure and are partially attached to the back surface of the wafer. As shown in FIG. 1C and FIG. 1D, the particles 102 will be produced on the end part 101 due to corrosion, and then the particles 102 will be attached to the back surface of the wafer 13. This part of the particles will be conveyed to a common path conveying area/environment transition buffer area along with the wafer, and will worsen the environment of a common path due to long-term accumulation, so that the particles exit on a subsequent wafer. Secondly, the back surface of the wafer carries the particles to enter a lithography cavity and the particles are accumulated on a surface of a base carrying the wafer for a long time, which may cause the wafer to not be flat on the base and causes an abnormal process, thereby directly affecting the yield of wafers. Therefore, an ejector pin structure is needed to reduce the particles on the back of the wafer.

The embodiments of the disclosure provide an ejector pin structure, which at least includes an end part and an ejector rod. The end part includes a convex structure and an inverted trapezoid-like structure located below the convex structure. The convex structure is configured to support an object to be processed. A projection area of the convex structure in a horizontal plane is less than that of the inverted trapezoid-like structure in the horizontal plane.

Here, the ejector rod may be cylindrical or prismatic. The ejector rod may be made of a stainless steel material, a metal material, or a ceramic material. The ejector rod and the end part may be integrated, so as to facilitate manufacturing, or may also be separated, for example be connected with each other in a detachable mode. The object to be processed may be a wafer, a substrate, or other objects.

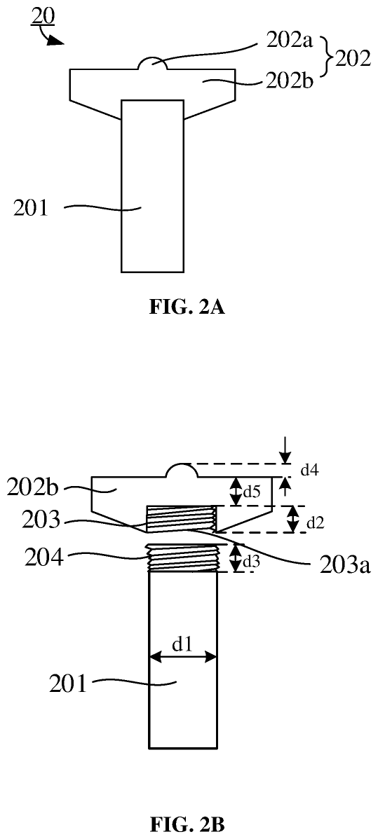

FIG. 2A is a schematic diagram illustrating composition structures of an ejector pin structure provided by the embodiments of the disclosure. The ejector pin structure provided by the embodiments of the disclosure is interpreted in detail with reference to FIG. 2A. As shown in FIG. 2A, the ejector pin structure 20 includes an ejector rod 201 and an end part 202. The end part 202 includes a convex structure 202a and an inverted trapezoid-like structure 202b located below the convex structure 202a. It can be seen from FIG. 2A that a projection area of the convex structure 202a in a horizontal plane is less than that of the inverted trapezoid-like structure 202b in the horizontal plane. By the convex structure, the contact area between the back surface of the wafer and the end part of the ejector pin structure can be reduced, so as to reduce production of the particles and improve the environment of the cavity. Moreover, by the inverted trapezoid-like structure, the connection between the ejector rod and the end part is facilitated, so that the position where the end part falls into a channel of a heating assembly is more appropriate.

In some embodiments, the end part and the ejector rod are detachably connected to each other. For example, the end part and the ejector rod may be connected by using a clamping hook, may be in key connection, clamping connection, or pin connection, or may be in threaded connection, which can be selected by those skilled in the art according to requirements, and is not be limited here.

The detachable connection between the end part and the ejector rod is described by taking the threaded connection as an example. As shown in FIG. 2B, the inverted trapezoid-like structure 202b has a threaded hole 203 opened downward. The ejector rod 201 has external threads 204. The threaded hole 203 has internal threads 203 matched with the external threads 204, so that the inverted trapezoid-like structure can be screwed on the ejector rod 201 through the internal screws 203a and the external screws 204. Therefore, when the end part is worn, only the end part can be disassembled without removing the heating assembly located below the end part, which reduces the disassembly loss of the heating assembly, prolongs the service life of the heating assembly, and shortens the replacement time and return time of the ejector pin structure. Meanwhile, the surface of the inverted trapezoid-like structure has edges and corners, so that the disassembly tool is easier to clamp the end part during disassembling and assembling, and does not easy to slip, so as to facilitate disassembling and assembling.

The detachable connection between the end part and the ejector rod is described by taking the clamping connection as an example. The inverted trapezoid-like structure has a clamping groove opened downward. The ejector rod has a radially outward clamping bump. It can be understood that the end part has a concave part, and the ejector rod has the bump, so that the bump may be stably clamped inside the convex part without relative movement. During implementing, the concave part may be T-shaped, and the bump may be T-shaped. During assembling, the end part is placed on the ejector rod, and the clamping bump is located in the clamping groove by rotating the end part.

In some embodiments, the ejector pin structure is made of ceramic. During implementing, the ceramic, such as alumina ceramic or silicon nitride ceramic, with excellent performance of high temperature resistance, corrosion resistance, and the like may be used, which can reduce the production of particles.

In some embodiments, the projection area of the inverted trapezoid-like structure in a horizontal plane is greater than a projection area of the ejector rod in the horizontal plane. Here, the ejector rod structure needs to penetrate through the heating assembly, and after an object to be processed is driven to move downward to be placed on the heating assembly, the back surface of the object to be processed is in contact with an upper surface of the heating assembly. At this moment, the end part of the ejector rod structure is placed in a channel of the heating assembly, which can play a positioning effect. Thus, the projection area of the inverted trapezoid-like structure in the horizontal plane needs to be greater than the projection area of the ejector rod in the horizontal plane.

In some embodiments, a dimension of a cross section of the ejector rod is 2 to 5 mm, a height of a connecting part between the end part and the ejector rod is 0.5 to 3 mm, a height of the convex structure is 0.5 to 1.5 mm, and a height of the inverted trapezoid-like structure is 1 to 5 mm. A length of a contact surface between the object to be processed and the end part of each ejector pin structure is 0.3 to 1 mm.

As shown in FIG. 2B, the cross sectional area d1 of the ejector rod 201 is 3 mm, the height d2 of the threaded hole 203 (the internal threads 203a) is 1 mm, and the height d3 of the external threads 204 is also 1 mm. The height d4 of the convex structure is 1 mm, the distance d5 between the top of the threaded hole 203 and the top of the inverted trapezoid-like structure 202b is 1 mm, and the height of the inverted trapezoid-like structure is the sum of d2 and d5, that is, 2 mm. As such, the contact length between the ejector pin structure and the back surface of the object to be processed is 0.5 mm, and the contact length between the abovementioned ejector pin structure and the back surface of the object to be processed is 2 mm. It can be seen that the ejector pin structure provided by the embodiments of the disclosure reduces the contact length or the contact area between the ejector pin structure and the back surface of the object to be processed, so as to reduce the production of the particles, and improve the environment in the cavity.

In some embodiments, the convex structure is located at a position of a vertical central line of the ejector rod, and the convex structure is a hemisphere with a radius of 0.5 to 1.5 mm. During implementing, the radius of the convex structure may be 1 mm.

Here, the convex structure is hemispherical, which can reduce the contact area between clean gas or plasma and the convex structure and can further reduce the corrosion to the convex structure, thereby reducing production of the particles. Meanwhile, the surface of the hemispherical structure is smooth, which can reduce the scratch of the object to be processed.

In some embodiments, a length of a cross section of the end part is 3 to 10 mm. During implementing, the length of the cross section of the end part may be 6 mm.

A semiconductor processing device provided by the embodiments of the disclosure includes a cavity; an ejector pin structure, located in the cavity, as provided by the abovementioned embodiment, and configured to support a semiconductor; and a lifting assembly, configured to drive the ejector pin structure to move up and down.

The semiconductor processing device provided by the embodiments of the disclosure can be used in the process of forming a film by using a plasma enhanced chemical vapor deposition technology. Low temperature plasma is used as an energy source. The semiconductor is placed on a cathode capable of performing glow discharge at a low pressure. The semiconductor is heated to a predetermined temperature by using the glow discharge, and then a suitable amount of reaction gas is introduced. The gas forms a solid film on the surface of the semiconductor through a series of chemical reactions and plasma reactions. During a film forming process, the semiconductor is smoothly ascended from and descended on the heating assembly during a process that the lifting assembly drives the ejector pin structure to ascend and descend, so as to realize the conveying of the semiconductor.

In the embodiments of the disclosure, the used ejector pin structure at least includes an end part and an ejector rod. The end part includes a convex structure and an inverted trapezoid-like structure located below the convex structure. The convex structure is configured to support an object to be processed. The projection area of the convex structure in the horizontal plane is less than that of inverted trapezoid-like structure in the plane surface. The contact area between the back surface of the conductor and the end part of the ejector pin structure can therefore be reduced, so as to reduce production of the particles and improve the environment inside the cavity. Meanwhile, the connection between the ejector rod and the end part can be facilitated by the inverted trapezoid-like structure, so that the position where the end part falls into a channel of a heating assembly is more appropriate.

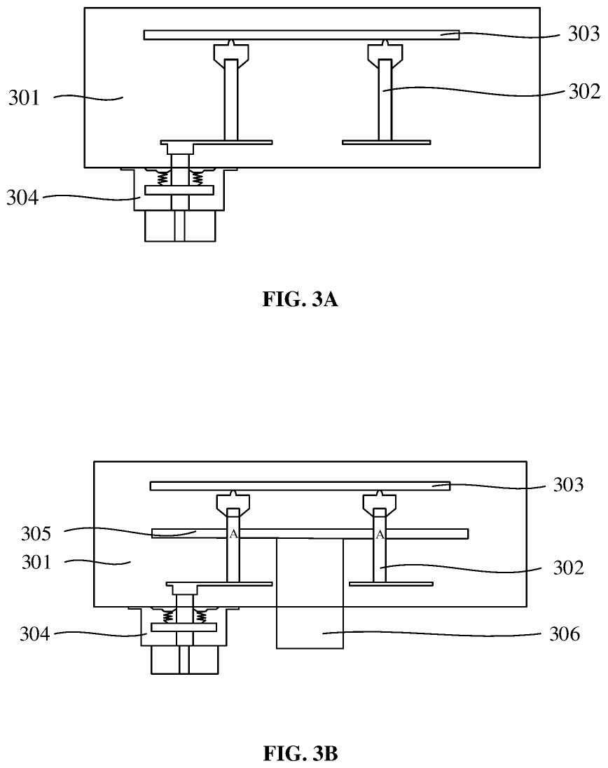

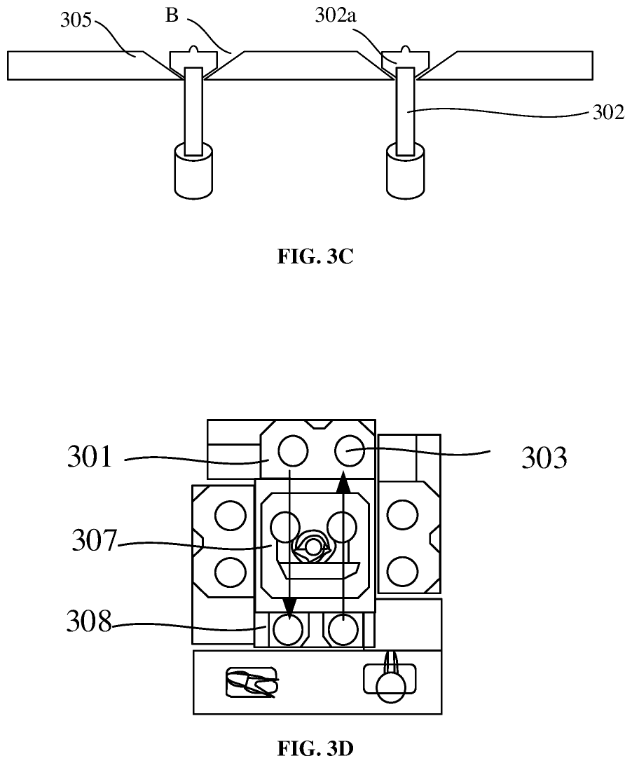

The semiconductor processing device provided by the embodiments of the disclosure will be interpreted in detail below with reference to FIG. 3A. As shown in FIG. 3A, the semiconductor processing device includes: a cavity 301, ejector pin structures 302 located inside the cavity 301, a semiconductor 303 located on the ejector pin structures 302, and a lifting assembly 304 configured to drive the ejector pin structure 302 to move up and down.

During implementing, the lifting assembly may be a lifting rod, or may be a lifting platform, which can be selected by those skilled in the art according to requirements, and is not limited here.

In some embodiments, as shown in FIG. 3B, the semiconductor processing device further includes: a heating assembly 305 located in the cavity 301, and configured to heat the semiconductor 303, and/or configured to carry the semiconductor 303. A plurality of channels A through which all ejector pin structures 302 penetrate are formed in the heating assembly 305.

Here, the heating assembly may be a heating plate or a heating disc. The heating plate or the heating disc may be made of a ceramic material. The heating assembly may be configured to heat the semiconductor; or the semiconductor may also be placed flat on the heating assembly, to be carried by the heating assembly; or the heating assembly can both heat the semiconductor and carry the semiconductor.

In some embodiments, as shown in FIG. 3C, a plurality of reserved spaces B, which are formed in such a manner that an inner wall of a top end of each of the channels A protrudes radially outwards, are also formed in the heating assembly 305. The end part 302a of the ejector pin structure 302 can be accommodated in the reserved space B. As such, the end part of the ejector pin structure does not have to be deliberately aligned with the reserved space B when entering the reserved space B, and the coordination between the end part of the ejector pin structure and the reserved space B is simpler. Further, the external diameter of the inverted trapezoid-like structure is gradually reduced from the top end to the bottom end, and the internal diameter of the reserved space B is gradually reduced from the top end to the bottom end. Thus, when the inverted trapezoid-like structure does not enter the reserved space B, one end, with a small external diameter, of the inverted trapezoid-like structure faces the reserved space B, and one end, with a large external diameter, of the reserved space B faces the inverted trapezoid-like structure, so that the inverted trapezoid-like structure enters the reserved space B more easily.

In some embodiments, an outer peripheral surface of the inverted trapezoid-like structure is an outer conical surface. An inner peripheral wall of the reserved space B is an inner conical surface. The inverted trapezoid-like structure and the reserved space B of this shape are easier to be machined.

In some embodiments, the lifting assembly includes a lifting platform, a connecting rod, and an outer driving part, and the lifting platform is connected to the outer driving part through the connecting rod. Here, the bottom of the ejector rod of the ejector pin structure is in contact with the lifting platform. The lifting platform is configured to support the ejector pin structure. The outer driving part may be a driving motor, or may also be an electric cylinder, an air cylinder, or an oil cylinder, for example a pressure ring lifting cylinder. Those skilled in the art can select it according to requirements, and no limits are made thereto here.

In some embodiments, the device includes three ejector pin structures which are in regular triangle distribution. Thus, when the three ejector pin structures jack up the semiconductor simultaneously, the semiconductor is stressed more uniformly, and the semiconductor is supported more stably, which can improve the stability of the semiconductor during an up-down movement process.

In some another embodiments, the device may include a plurality of ejector pin structures. Vertexes of each adjacent two ejector pin structures are connected into a regular polygon, which may be, for example, a square or a regular pentagon. The orthographic projection of the center of the regular polygon on an upper platform plane of the lifting platform coincides with the center of the lifting platform, the stability of the semiconductor during moving thus can be further improved.

In some embodiments, as shown in FIG. 3B, the device may further include: a supporting assembly 306 that is located below the heating assembly, at a center of the heating assembly 305 and extends downwards. Here, the supporting assembly is configured to support the heating assembly.

The embodiments of the disclosure provide a semiconductor processing device. Referring to FIG. 3A and FIG. 3B simultaneously, the device includes a cavity 301, an ejector pin structure 302 located in the cavity 301, as described in any one of the abovementioned embodiments, and configured to support the semiconductor 303; a lifting assembly 304, configured to drive the ejector pin structure 302 to move up and down; a conveying area 307, located outside the cavity 301, and configured to convey a semiconductor 303 having been subjected to a previous processing process; and an environment transition buffer area 308, adjacent to the conveying area 307 and configured to store a semiconductor 303 to be subjected to a next processing process. A direction as shown by an arrow in FIG. 3D is a semiconductor conveying path. During implementing, when the processing of the semiconductor 303 is completed in the cavity 301, the ejector pin structure jacks up the semiconductor 303. The semiconductor 303 is removed from the cavity 301 by a mechanical arm, and is conveyed to the conveying area 307, and then the semiconductor 303 is conveyed to the environment transition buffer area 308 by the mechanical arm. In this buffer area, the semiconductor 303 may be subjected to vacuumizing treatment. The transition buffer area can serve as a transition cavity of the semiconductor before conveying from a non-vacuum state to another high-vacuum state, so that a certain vacuum degree is reached, and a much vacuumizing time from atmosphere to the high vacuum can be shortened. Then, the mechanical arm will convey the semiconductor to the cavity for a next processing process, for example, a cavity for performing lithography processing.

The lithography processing is a process for establishing patterns on the surfaces of different devices and circuits by a series of production steps. A final pattern of the semiconductor device is established on a surface of the semiconductor by stacking layer by layer through a plurality of masks according to a specific sequence. The lithography process includes main processes of glue coating, exposure, development, and the like. The exposure is that a photoresist layer is irradiated by taking an exposure lamp or other radiation sources as an exposure light source, so as to transfer the patterns onto the photoresist layer. The development is that the photoresist unpolymerized after the exposure is chemically decomposed, so as to transfer the patterns into the photoresist. During exposure, if there is a convex or concave abnormality on the back surface of the semiconductor, the formation of an image on a front surface will be affected.

It can be seen from the above that semiconductors having been processed in the cavity will be conveyed to the conveying area and an environment transition buffer area through the mechanical arm. By using the ejector pin structure provided by the embodiments of the disclosure, the production of the particles are reduced, the environment in the cavity is improved, and the environments of the conveying area and the environment transition buffer area are also improved. Thus, when the semiconductor enters the cavity for a next processing process, the particles on the back surface of the semiconductor can be reduced, or there will not even be particles. Therefore, the problem that the levelness of the semiconductor on the base is affected by presence of the particles on the back surface of the semiconductor will not occur, so that the influence on the lithography process is reduced, and the production yield of the semiconductors is improved.

In some embodiments, a sensor may also be arranged in the environment transition buffer area, to detect defects of the semiconductors, which is beneficial to performing batch production of the semiconductors.

The embodiments of the disclosure provide a method for using a semiconductor processing device, applied to the abovementioned semiconductor processing device. The device includes: a cavity and a lifting assembly. The cavity includes injector pin structures and a heating assembly. The ejector pin structures are configured to support a semiconductor. The ejector pin structure includes an ejector rod and an end part that are connected detachably. The end part includes a convex structure and an inverted trapezoid-like structure located below the convex structure. A projection area of the convex structure in a horizontal plane is less than a projection area of the inverted trapezoid-like structure in the horizontal plane. The heating assembly is located in the cavity and is configured to heat the semiconductor, and/or, configured to carry the semiconductor. A plurality of channels through which all ejector pin structures penetrate are formed in the heating assembly. The lifting assembly is configured to drive the ejector pin structure to move up and down.

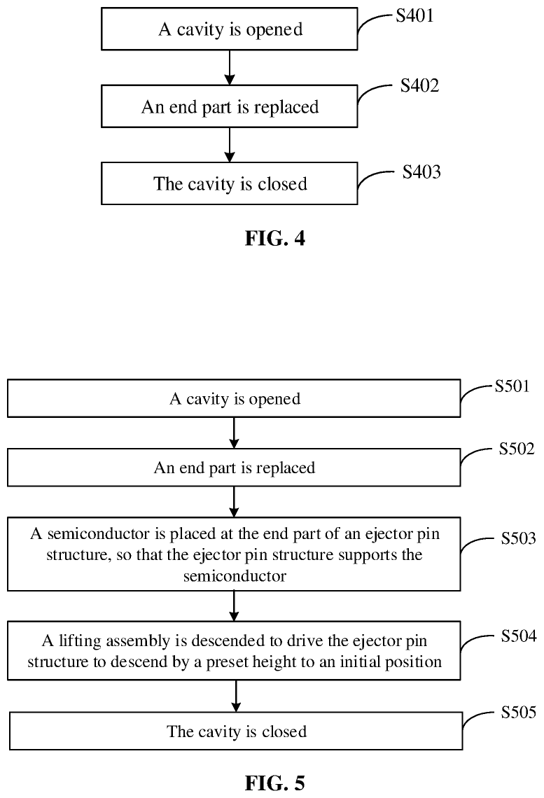

As shown in FIG. 4, in the method includes the following steps.

At S401, a cavity is opened.

At S402, an end part is replaced.

At S403, the cavity is closed.

It can be understood that the device in this embodiment may be understood with reference to FIG. 3A. Here, in some implementations, if the end part of the ejector pin structure is worn and thus the ejector pin structure needs to be replaced, the cavity needs to be opened first, so that the heating assembly is disassembled, and the ejector pin structure is replaced, then the heating assembly is mounted, and the cavity is closed. In this way, it is estimated that it will take 10 hours to replace the ejector pin structure in each cavity in the machine. In the embodiments of the disclosure, the semiconductor processing device includes a cavity and a lifting assembly. The cavity includes an ejector pin structure and a heating assembly. Since the ejector rod and the end part of the ejector pin structure are connected detachably, only the end part is replaced without removing the heating assembly during replacing, so as to shorten the replacement time, which is estimated to take 7 hours. Thus, the semiconductor processing efficiency can be improved without affecting normal shipment and production, and the production capacity is improved.

In some embodiments, after S402, the method further includes that: the ejector pin structure is corrected to a preset height. Thus, the lifting height before and after replacing the ejector pin structure can be kept the same, so that the conveying height of a mechanical arm does not need to be adjusted repeatedly during subsequent conveying of the semiconductor. During implementing, the height of the ejector pin may be adjusted manually by using an ejector pin height tool, and may also be regulated by using an automatic height adjusting program, so as to realize precise assembly and rapid assembly.

The embodiments of the disclosure provide a method for using a semiconductor processing device, applied to the abovementioned semiconductor processing device. The device includes: a cavity and a lifting assembly. The cavity includes injector pin structures and a heating assembly. The ejector pin structures are configured to support a semiconductor. The ejector pin structure includes an ejector rod and an end part that are connected detachably. The end part includes a convex structure and an inverted trapezoid-like structure located below the convex structure. A projection area of the convex structure in a horizontal plane is less than a projection area of the inverted trapezoid-like structure in the horizontal plane. The heating assembly is located in the cavity and is configured to heat the semiconductor, and/or, is configured to carry the semiconductor. A plurality of channels through which all ejector pin structures penetrate are formed in the heating assembly. The lifting assembly is configured to drive the ejector pin structure to move up and down.

It can be understood that the device in this embodiment may be understood with reference to FIG. 3A. As shown in FIG. 5, the method includes the following steps.

At S501, a cavity is opened.

At S502, an end part is replaced.

At S503, a semiconductor is placed at the end part of the ejector pin structure, so that the ejector pin structure supports the semiconductor.

Here, the semiconductor is placed on the ejector pin structure through the mechanical arm, so that the back surface of the semiconductor is in contact with the ejector pin structure, and the ejector pin structure supports the semiconductor.

At S504, the lifting assembly is descended to drive the ejector pin structure to descend by a preset height to an initial position.

At S505, the cavity is closed.

It can be understood that not only the process of replacing the ejector pin structure is included here, but also the process of placing the semiconductor inside the cavity to perform processing on the semiconductor is included. For example, film deposition is performed on the semiconductor. Here, S503 and S504 are the steps of placing the semiconductor into the cavity. During the process, the lifting assembly drives the ejector pin structure to move upwards, so that the height of the semiconductor is greater than that of the heating assembly. The mechanical arm can hold the semiconductor to place the semiconductor on the ejector pin structure, and a space between the top end of the ejector pin structure and the heating assembly is configured to reserve position for the mechanical arm. After the mechanical arm retracts, the lifting assembly descends to drive the ejector pin structure to descend by the preset height to the initial position. During the process, the semiconductor is placed on the heating assembly which can carry the semiconductor. When the heating assembly heats the semiconductor, the ejector pin structure plugs the channel and plays a role of heat conduction, so that the semiconductor can be heated more uniformly.

In some embodiments, the method further includes the following steps.

At S506, the lifting assembly is ascended to drive the ejector pin structure to ascend from the initial position to the preset height.

At S507, the semiconductor is removed from the end part of the ejector pin structure.

It can be understood that S506 and S507 are processes of removing the semiconductor from the cavity. The lifting assembly ascends to drive the ejector pin structure to ascend to the preset height from the initial position. At this moment, the heating assembly does not carry the semiconductor, and the ejector pin structure supports the semiconductor. The semiconductor may be removed from the ejector pin structure by the mechanical arm, so as to convey out of the cavity.

In several embodiments provided by the disclosure, it is to be understood that the disclosed device and method may be implemented in a non-target mode. The device embodiment described above is only schematic, and for example, division of the units is only logic function division, and other division manners may be adopted during practical implementation. For example, a plurality of units or components may be combined or integrated into another system, or some characteristics may be neglected or not executed. In addition, the components shown or discussed are coupled to each other, or directly coupled.

The abovementioned units described as separate parts may be or may not be physically separate and the parts shown as units may be or may not be physical elements, which may be located in one place or distributed to a plurality of network elements. Some or all of the units may be selected to achieve the objectives of the solutions of the embodiments according to practical requirements.

The characteristics disclosed in several method or device embodiments provided in the disclosure may be freely combined without conflicts to obtain new method embodiments or device embodiments.

The abovementioned descriptions are only some implementation modes of the disclosure, but the scope of protection of the embodiments of the disclosure are limited thereto. Any variation or replacement readily conceived by a person skilled in the art within the technical scope disclosed in the disclosure shall fall within the scope of protection of the disclosure. Therefore, the scope of protection of the embodiments of the disclosure shall be subject to the scope of protection of the claims.

What is claimed is:

1. An ejector pin structure, at least comprising an end part and an ejector rod, wherein
the end part comprises a convex structure and an inverted trapezoid-like structure located below the convex structure;
the convex structure is configured to support an object to be processed; and
a projection area of the convex structure in a horizontal plane is less than a projection area of the inverted trapezoid-like structure in the horizontal plane.

2. The structure according to claim 1, wherein the end part and the ejector rod are connected detachably.

3. The structure according to claim 2, wherein the ejector pin structure is made of ceramic.

4. The structure according to claim 3, wherein the projection area of the inverted trapezoid-like structure in the horizontal plane is greater than a projection area of the ejector rod in the horizontal plane.

5. The structure according to claim 4, wherein a dimension of a cross section of the ejector rod is 2 to 5 mm, a height of a connecting part between the end part and the ejector rod is 0.5 to 3 mm, a height of the convex structure is 0.5 to 1.5 mm, and a height of the inverted trapezoid-like structure is 1 to 5 mm; and a length of a contact surface between the object to be processed and the end part of each ejector pin structure is 0.3 to 1 mm.

6. The structure according to claim 5, wherein the convex structure is located at a position of a vertical central line of the ejector rod, and the convex structure is a hemisphere with a radius of 0.5 to 1.5 mm.

7. The structure according to claim 6, wherein a length of a cross section of the end part is 3 to 10 mm.

8. A semiconductor processing device, comprising:
a cavity;
ejector pin structures, located in the cavity and configured to support a semiconductor;
the ejector pin structure at least comprising an end part and an ejector rod,
wherein the end part comprises a convex structure and an inverted trapezoid-like structure located below the convex structure;
the convex structure is configured to support an object to be processed; and
a projection area of the convex structure in a horizontal plane is less than a projection area of the inverted trapezoid-like structure in the horizontal plane; and
a lifting assembly, configured to drive the ejector pin structure to move up and down.

9. The device according to claim 8, further comprising:
a heating assembly, located in the cavity and configured to perform at least one of heating the semiconductor or carrying the semiconductor,
wherein a plurality of channels through which all ejector pin structures penetrate are formed in the heating assembly.

10. The device according to claim 9, wherein a plurality of reserved spaces formed in such a manner that an inner wall of a top end of each of the channels protrudes radially outwards are further formed in the heating assembly; and
the end part of the ejector pin structure is able to be accommodated in the reserved space.

11. The device according to claim 8, wherein the lifting assembly comprises a lifting platform, a connecting rod, and an outer driving part, and wherein the lifting platform is connected to the outer driving part through the connecting rod.

12. The device according to claim 11, comprising three ejector pin structures which are in regular triangle distribution.

13. The device according to claim 9, further comprising a supporting assembly that is located below the heating assembly, at a center of the heating assembly and extends downward.

14. The device according to claim 8, further comprising:
a conveying area, located outside the cavity and configured to convey a semiconductor having been subjected to a previous processing process; and
an environmental transition buffer area, adjacent to the conveying area and configured to store a semiconductor to be subjected to a next processing process.

15. A method for using a semiconductor processing device, wherein the device comprises:
a cavity and a lifting assembly, wherein the cavity comprises ejector pin structures and a heating assembly;
the ejector pin structures are configured to support a semiconductor; the ejector pin structure comprises an ejector rod and an end part that are connected detachably; the end part comprises a convex structure and an inverted trapezoid-like structure located below the convex structure; a projection area of the convex structure in a horizontal plane is less than a projection area of the inverted trapezoid-like structure in the horizontal plane;
the heating assembly is located in the cavity and is configured to perform at least one of heating the semiconductor or carrying the semiconductor; a plurality of channels through which all ejector pin structures penetrate are formed in the heating assembly;
the lifting assembly is configured to drive the ejector pin structure to move up and down;
the method comprises:
opening the cavity;
replacing the end part; and
closing the cavity.

16. The method according to claim 15, after replacing the end part, further comprising:
correcting the ejector pin structure to a preset height.

17. The method according to claim 16, further comprising:
placing the semiconductor at the end part of the ejector pin structure, so that the ejector pin structure supports the semiconductor; and
descending the lifting assembly to drive the ejector pin structure to descend by a preset height to an initial position.

18. The method according to claim 17, further comprising:
ascending the lifting assembly to drive the ejector pin structure to ascend from the initial position to the preset height; and
removing the semiconductor from the end part of the ejector pin structure.
